(19) United States
(12) Patent Application Publication
(10) Pub. No.: US 2008/0150003 A1
(43) Pub. Date: Jun. 26, 2008

(54) Electron blocking layers for electronic devices

(76) Inventors: Jian Chen, Mountain View, CA (US); Xiangfeng Duan, Mountain View, CA (US); Karen Cruden, Pleasanton, CA (US); Chao Liu, San Jose, CA (US); Madhuri L. Nallabolu, Sunnyvale, CA (US); Srikanth Ranganathan, Mountain View, CA (US); Francisco Leon, Palo Alto, CA (US); J. Wallace Parce, Palo Alto, CA (US)

Correspondence Address: STERNE, KESSLER, GOLDSTEIN & FOX P.L.L.C., 1100 NEW YORK AVENUE, N.W., WASHINGTON, DC, 20005, US

(21) Appl. No.: 11/641,956

(22) Filed: Dec. 20, 2006

(51) Int. Cl. H01L 29/792; H01L 21/336

(52) U.S. Cl. 257/324; 438/287; 257/E21.409; 257/E29.309

(57) ABSTRACT

Methods and apparatuses for electronic devices such as non-volatile memory devices are described. The memory devices include a multi-layer control dielectric, such as a double or triple layer. The multi-layer control dielectric includes a combination of high-k dielectric materials such as aluminum oxide (Al2O3), hafnium oxide (HfO2), and/or hybrid films of hafnium aluminum oxide. The multi-layer control dielectric provides enhanced characteristics, including increased charge retention, enhanced memory program/erase window, improved reliability and stability, with feasibility for single or multistate (e.g., two, three or four bit) operation.

### BACKGROUND OF THE INVENTION

1. Field of the Invention

The present invention relates to memory devices, and more particularly, to flash memory devices.

2. Background Art

Non-volatile memory devices, such as flash memory devices, are memory devices that can store information even when not powered. A flash memory device stores information in a charge storage layer that is separated from a “control gate.” A voltage is applied to the control gate to program and erase the memory device by causing electrons to be stored in, and discharged from the charge storage layer.

A control dielectric is used to isolate the control gate from the charge storage layer. It is desirable for the control dielectric to block charge flow between the charge storage layer and control gate. High-k dielectric layers can serve as efficient charge-blocking layers. They have been used as the control dielectric layer for flash memory devices, such as Samsung's TANOS devices, to enable the down-scaling of flash memory devices below 40 nm. The control dielectric layer may be a single layer of Al₂O₃, typically with a thickness of less than 20 nm. However, Al₂O₃ does not completely block charge transport and leads to program and erase saturation at lower voltage windows.

What is needed are improved, longer lasting non-volatile memory devices, with improved charge blocking characteristics. Furthermore, multi-state memory devices exist, which can store more than one bit of information per memory cell. What is needed are improved multi-state memory devices that can store multiple bits per cell with relatively large program/erase voltage windows of operation.

### BRIEF SUMMARY OF THE INVENTION

The enhancement of performance and charge retention properties of nonvolatile memory devices using metal or semiconductor nanocrystals (such as colloidal quantum dots or quantum dots formed using processes such as chemical vapor deposition or physical vapor deposition) or nonconductive nitride based charge trapping layers embedded in a high-k dielectric matrix, is important to overcome the scaling limitations of conventional non-volatile memories beyond the 50 nm technology node and to fully enable reliable multi-bit operation.

The present invention relates to methods, systems and apparatuses for improved electronic devices, such as memory devices, having enhanced characteristics including increased charge retention, enhanced memory program/erase window, improved reliability and stability, with feasibility for single or multistate (e.g., two, three or four bit) operation. The use of a multi-layer control dielectric, such as a double or triple layer control dielectric, in a nonvolatile memory device is disclosed for the first time. The multi-layer control dielectric includes a combination of high-k dielectric materials such as aluminum oxide (Al₂O₃), hafnium oxide (HfO₂), and/or hybrid films of hafnium aluminum oxide (HfAlOx, wherein x is a positive integer, e.g., 1, 2, 3, 4, etc.) therein.

In an embodiment, a double control dielectric layer for a memory device is disclosed, including a control dielectric layer of Al2O3, and a thin charge blocking layer of HfO2 (or HfAlO3). The layer of HfO2 provides an efficient charge blocking layer to block electron current flow from the charge storage layer to the control gate during a programming operation of the memory device.

In another embodiment, a double control dielectric layer for a memory device is disclosed including a control dielectric layer of Al2O3 and a layer of HfO2 between the control dielectric and the control gate. The layer of HfO2 suppresses a tunneling current from a control gate of the memory device during erase operations which can lead to large over-erase voltages.

In another embodiment, a triple control dielectric layer for a memory device is disclosed. In an embodiment, the triple control dielectric layer includes a first layer of HfO2 (or HfAlO3) adjacent to the charge storage layer of the device, a second layer of HfO2 adjacent to the control gate of the memory device, and a layer of Al2O3 between the first and second layers of HfO2. The second layer of HfO2 blocks electron current from the control gate to the charge storage layer during the erase operation of the memory device.

The thickness of single or dual layers of HfO2 (or HfAlO3) can be kept very thin while still efficiently blocking current flow. For example, in an embodiment, the thickness is less than about 4 nm. In another example embodiment, the thickness is less than about 2 nm.

In embodiments, the use of such a double or triple layer control dielectric provides the unexpected result of achieving a very large program/erase window (e.g., on the order of about 12 volts or greater), while still providing for good charge retention and programming/erasing speed, which is important in making reliable multi-bit/cell memory devices with scaling to smaller node sizes. Furthermore, in an embodiment, the charge-blocking layer dramatically reduces the amount of current that flows through the control dielectric during the program, erase, and read operations, which enables flash memory devices that can endure a large number of program/erase cycles without significant drift in operation voltages.

In embodiments, materials other than HfO2 may be used, including further high-k dielectric materials, such as Gd2O3, Yb2O3, Dy2O3, Nb2O5, Y2O3, La2O3, ZrO2, TiO2, Ta2O5, SrTiO3, BaxSr1-xTiO3, ZrxSi1-xOy, HfxSi1-xOy, AlxZr1-xO2, or Pr2O, for example.

These and other objects, advantages and features will become readily apparent in view of the following detailed description of the invention. Various ones of the foregoing objects, advantages, and/or features may impart patentability independently of the others.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a cross-sectional view of a memory device, according to an example embodiment of the present invention.

FIGS. 2-4 show cross-sectional views of charge storage layers, according to example embodiments of the present invention.

FIG. 5 shows an example contiguous charge storage layer, according to an example embodiment of the present invention.

FIG. 6 shows an example non-contiguous charge storage layer, according to an example embodiment of the present invention.

FIGS. 7A and 7B shows simulation plots related to a combination control dielectric layer, according to embodiments of the present invention.

FIGS. 8A-8C and 9A-9D show plots related to a program/erase window for various gate stacks having one or more charge blocking layers, according to example embodiments of the present invention.

FIG. 10 shows a flowchart providing example steps for forming an electronic device, such as a memory device, according to example embodiments of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

It should be appreciated that the particular implementations shown and described herein are examples of the invention and are not intended to otherwise limit the scope of the present invention in any way. Indeed, for the sake of brevity, conventional electronics, manufacturing, semiconductor devices, and other functional aspects of the systems (and components of the individual operating components of the systems) may not be described in detail herein.

It should be understood that the spatial descriptions (e.g., “above”, “below”, “up”, “down”, “top”, “bottom”, etc.) made herein are for purposes of illustration only, and that devices of the present invention can be spatially arranged in any orientation or manner.

### Memory Device Embodiments

Embodiments of the present invention are provided in the following sub-sections for electronic devices, such as non-volatile memory devices, including flash memory devices. Furthermore, embodiments for enhanced memory devices, such as multistate memory devices, are described. These embodiments are provided for illustrative purposes, and are not limiting. The embodiments described herein may be combined in any manner. Additional operational and structural embodiments for the present invention will be apparent to persons skilled in the relevant art(s) from the description herein. These additional embodiments are within the scope and spirit of the present invention.

A conventional charge storage layer memory cell or structure is programmed by applying appropriate voltages to the source, drain, and control gate nodes of the memory structure for an appropriate time period. Electrons are thereby caused to tunnel or be injected (e.g., via channel hot electrons) from a channel region to a charge storage layer, which is thereby “charged.” The charge stored in the charge storage layer sets the memory transistor to a logical “1” or “0.” Depending on whether the memory structure includes an enhancement or depletion transistor structure, when the charge storage layer is positively charged or contains electrons (negative charge), the memory cell will or will not conduct during a read operation. When the charge storage layer is neutral (or positively charged) or has an absence of negative charge, the memory cell will conduct during a read operation by a proper choice of the gate voltage. The conducting or non-conducting state is output as the appropriate logical level. “Erasing” is the process of transferring electrons from the charge storage layer (or holes to the charge storage layer) (i.e., charge trapping layer). “Programming” is the process of transferring electrons onto the charge storage layer.

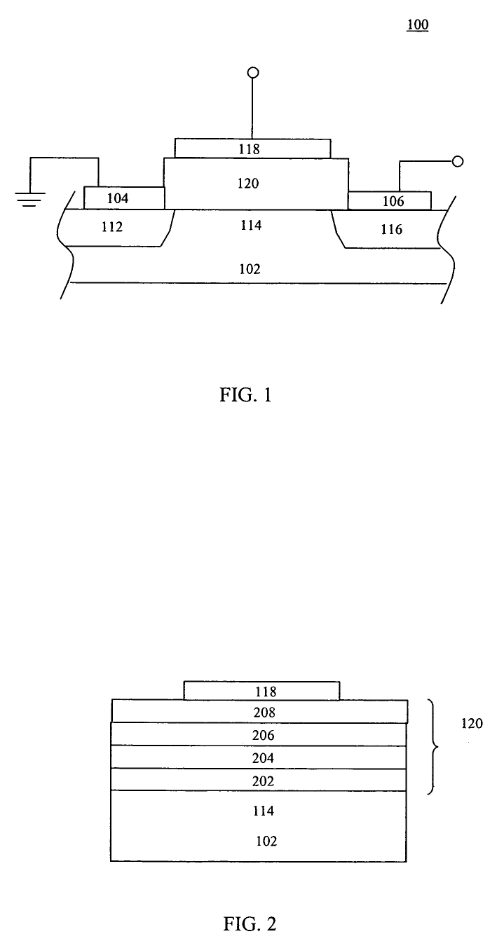

FIG. 1 shows a detailed cross-sectional view of a memory device 100, according to an example embodiment of the present invention. As shown in FIG. 1, memory device 100 is formed on a substrate 102. Memory device 100 includes source region 112, channel region 114, drain region 116, a control gate or gate contact 118, a gate stack 120, a source contact 104, a drain contact 106. Source region 112, channel region 114, and drain region 116 are configured generally similar to a transistor configuration. Gate stack 120 is formed on channel region 114. Gate contact 118 is formed on gate stack 120.

Memory device 100 generally operates as described above for conventional memories having charge storage layers. However, charge storage layer memory device 100 includes gate stack 120. Gate stack 120 provides a charge storage layer for memory device 100, and further features, as further described below. When memory device 100 is programmed, electrons are transferred to, and stored by the charge storage layer of gate stack 120. Gate stack 120 may include any type of charge storage layer or charge storage medium. Example charge storage layers are described below.

In the current embodiment, substrate 102 is a semiconductor type substrate, and is formed to have either P-type or N-type connectivity, at least in channel region 114. Gate contact 118, source contact 104, and drain contact 106 provide electrical connectivity to memory device 100. Source contact 104 is formed in contact with source region 112. Drain contact 106 is formed in contact with drain region 116. Source and drain regions 112 and 116 are typically doped regions of substrate 102, to have connectivity different from that of channel region 114.

As shown in FIG. 1, source contact 104 is coupled to a potential, such as a ground potential. Drain contact 106 is coupled to another signal. Note that source and drain regions 112 and 116 are interchangeable, and their interconnections may be reversed.

FIG. 2 shows an example cross-sectional view of gate stack 120, according to an embodiment of the present invention. In FIG. 2, gate stack 120 includes an tunneling dielectric layer 202, a charge storage layer 204, a charge blocking layer 206, and a control dielectric layer 208. In the example of FIG. 2, tunneling dielectric layer 202 is formed on channel region 114 of substrate 102 of memory device 100. Charge storage layer 204 is formed on tunneling dielectric layer 202. Charge blocking layer 206 is formed on charge storage layer 204. Control dielectric layer 208 is formed on charge blocking layer 206. As shown in FIG. 2, gate contact 118 is formed on control dielectric layer 208. Note that in embodiments, further one or more further layers of material may separate the layers of gate stack 120 and/or may separate gate stack 120 from substrate 102 and/or gate contact 118.

Charge storage layer 204 stores a positive or negative charge to indicate a programmed state of memory device 100, as described above. Charge storage layer 204 may include the materials described above, or otherwise known. During programming, a voltage applied to gate contact 118 creates an electric field that causes electrons to tunnel (e.g., or via hot electron injection) into charge storage layer 204 from channel region 114 through tunneling dielectric layer 202. The resulting negative charge stored in charge storage layer 204 shifts a threshold voltage of memory device 100. The charge remains in charge storage layer 204 even after the voltage is removed from gate contact 118. During an erase process, an oppositely charged voltage may be applied to gate contact 118 to cause electrons to discharge from charge storage layer 204 to substrate 102 through tunneling dielectric layer 202. Control dielectric layer 208 and charge blocking layer 206 isolate gate contact 118 from gate contact 118.

Charge storage layer 204 may include any type of charge storage or charge storage medium, including metal or semiconductor or dielectric nanoparticles. For example, charge storage layer 204 may include nanocrystals formed of a high work function (e.g., greater than 4.5 eV) metal such as ruthenium (Ru), and preferably having a size of less than about 5 nm. Such nanocrystals may be deposited on tunneling dielectric layer 202 by a variety of processes, such as chemical vapor deposition (CVD), atomic layer deposition (ALD) or physical vapor deposition (PVD), as is known in the art. Charge storage layer 204 may also include preformed colloidal metal or semiconductor or dielectric quantum dots (nanocrystals) deposited on tunneling dielectric layer 202. For example, such materials may be deposited by methods such as spin coating, spray coating, printing, chemical assembly, nano-imprints using polymer self-assembly and the like, such as described in U.S. Pat. No. 6,586,785, U.S. application Ser. No. 11/147,670, and U.S. application Ser. No. 11/495,188, which are each incorporated by reference herein their entirety. Charge storage layer 204 may also include a contiguous metal or semiconductor conductive layer, a non-contiguous metal or semiconductor conductive layer, a nonconductive nitride-based or other types of insulating charge trapping layer, a nonconductive oxide layer (e.g., SiO₂) having conductive elements disposed therein (e.g., silicon islands), a doped oxide layer, etc. For further description of charge storage layers that include nitrides, refer to U.S. Pat. No. 5,768,192, which is incorporated by reference herein in its entirety.

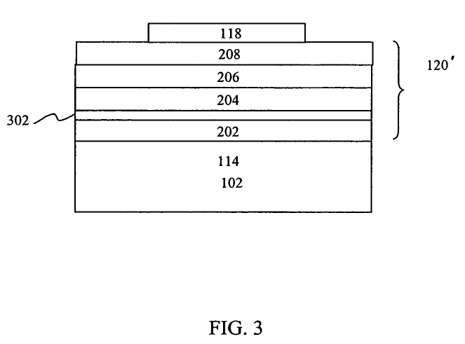

A surface of tunneling dielectric layer 202 (also referred to as “tunnel dielectric layer”) may be altered in order to provide an improved barrier to metal migration when metal quantum dots such as ruthenium (or other metal) are used for the charge storage material. For example, as shown in FIG. 3, gate stack 120′ may include a barrier layer 302 formed on tunneling dielectric layer 202 between tunneling dielectric layer 202 and charge storage layer 204. Barrier layer 302 can include, for example, a nitrogen containing compound such as nitride (Si₃N₄) or silicon oxynitride (SiOₓN_{y}, wherein x and y are positive numbers, 0.8, 1.5, etc., or other suitable barrier layer such as alumina (Al₂O₃). Barrier layer 302 changes the surface structure of tunneling dielectric layer 202 such that metal migration effects may be minimized. Where barrier layer 302 is made from a nitrogen compound, the nitrogen-containing layer may be formed by adding nitrogen or a “nitrogen-containing” compound (e.g., “nitriding”) to tunneling dielectric layer 202 (e.g., which may be SiO₂). In an embodiment, the nitrogen or nitrogen-containing compound may be deposited on tunneling dielectric layer 202 using a chemical vapor deposition (CVD) process, such as low pressure CVD (LPCVD) or ultra high vacuum CVD (UHVCVD). The nitrogen-containing layer may be in direct contact with tunneling dielectric layer 202.

UHVCVD of barrier layer 302 may be more controllable than LPCVD, as the UHVCVD generally occurs more slowly, and therefore the growth rate may be more closely regulated. The nitrogen-containing layer may be formed as a result of deposition from the reaction of such gases as silane (or other silicon source precursor such as dichlorosilane, or disilane) and ammonia (or other nitrogen species such as plasma-ionized nitrogen, N₂O or NO), or a surface reaction to a reacting gas such as ammonia (or other nitrogen species such as plasma-ionized nitrogen, N₂O or NO). Dichlorosilane and ammonia gas in combination with a co-flow of some inert gas and oxygen-containing gas may be used for growth of the nitrogen-containing layer. Barrier layer 302 impedes penetration of metal nanoparticles/quantum dots of charge storage layer 204 into tunneling dielectric layer 202, such that contamination of tunnel dielectric layer 202, which may result in leakage, is avoided.

A thickness of barrier layer 302 is preferably configured to ensure that carrier traps included in nitride structures do not dominate the charge storage aspects of the semiconductor device being formed. In an embodiment, a desired thickness for barrier layer 302 is less than 10 angstroms. In further embodiments, the desired thickness may be 5 angstroms or less. The relative thicknesses of tunneling dielectric layer 202 and barrier layer 302 can be tailored to optimize electrical performance and metal migration barrier functions. The thickness of barrier layer 302 should be at least that required to ensure generally uniform coverage of tunneling dielectric layer 202 by barrier layer 302. In an embodiment where silicon oxynitride is utilized as barrier layer 302, the concentration of nitrogen within the silicon oxynitride may be greater than about 5%, for example. A percentage concentration of nitrogen included in the silicon oxynitride can be controlled such that the trade-off between the barrier function of the nitrogen layer against metal migration from metal quantum dots (when in charge storage layer 204) and the inclusion of traps due to nitride concentration is regulated.

In an embodiment, tunneling dielectric layer 202 is SiO₂ and substrate 102 is silicon. In an embodiment, charge blocking layer 206 is formed of a high-k dielectric material, such as Al₂O₃, HfO₂, HfSiO₂, ZrO₂, HfAlO₃, etc., preferably HfO₂ or HfAlO₃. In further embodiments, charge blocking layer 206 may be formed of other high-k dielectric materials, such as Gd₂O₃, Yb₂O₃, Dy₂O₃, Nb₂O₅, Y₂O₃, La₂O₃, ZrO₂, TiO₂, Ta₂O₅, SrTiO₃, BaxSr1-xTiO₃, ZrxSi1-xOy, HfxSi1-xOy, AlxZr1-xO₂, or Pr₂O, for example. In an embodiment, control dielectric layer 208 is formed of Al₂O₃.

In embodiments, charge blocking layer 206 has a higher dielectric constant than control dielectric layer 208. For example, in one embodiment, control dielectric layer 208 is Al₂O₃, which as a dielectric constant of approximately 9, and charge blocking layer 206 is HfO₂, which has a dielectric constant of less than 25, e.g., around 22, when deposited. In another embodiment, control dielectric layer 208 is SiO₂, which has a dielectric constant of approximately 4, while charge blocking layer is HfO₂.

In an embodiment, charge blocking layer 206 is formed of a material having a gradient. For example, the material may have a gradient of band gap value and/or dielectric constant which increases or decreases from a first surface of charge blocking layer 206 (e.g., a surface of charge blocking layer 206 adjacent to charge storage layer 204) to a second surface of charge blocking layer 206 (e.g., a surface of charge blocking layer 206 adjacent to control dielectric layer 208). In another embodiment, charge blocking layer 206 comprises a plurality of layers of materials. For example, charge blocking layer 206 may be formed of a plurality of layers, such that as the layer closest to charge storage layer 204 is formed of a relatively high band gap material, while the layer(s) further from charge storage layer 204 have a progressively lower band gap material. This may be desirable when charge storage layer 204 comprises isolate particles (e.g., nanoparticles, quantum dots), because a relatively higher band gap material allows less tunneling between particles than a lower band gap material. SiO₂, Al₂O₃, HfAlO₂ are example materials having relatively high band gap. For instance, in an example three-layer embodiment for charge blocking layer 206, a first layer (closest to charge storage layer 204) may be Al₂O₃, a second (middle) layer may be HfAlO₂, and a third layer (furthest from charge storage layer 204) may be HfO₂ (which has a relatively low band gap). In an example two-layer embodiment for charge blocking layer 206, the first layer (closest to charge storage layer 204) may be SiO2, and the second layer is HfO₂, which has a relatively high dielectric constant (for effective charge blocking) and a low band gap. As described above, control dielectric layer 208 may be a material such as Al₂O₃ or SiO₂.

In an embodiment, charge blocking layer 206 may be doped. For example, charge blocking layer 206 may be doped with dopant materials, such as a rare earth metal or silicate. In an embodiment, charge blocking layer 206 is formed to be relatively thin, such as less than 2 nm, to reduce trapping of electrons by the high dielectric material of charge blocking layer 206.

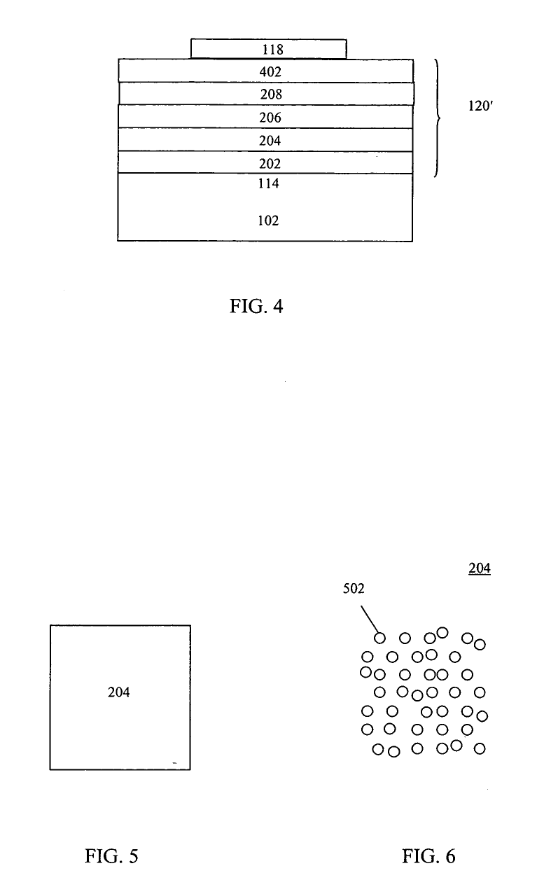

FIG. 4 shows another example cross-sectional view of gate stack 120″, according to an embodiment of the present invention. The configuration of gate stack 120″ in FIG. 4 is generally similar to FIG. 2, except that in FIG. 4, gate stack 120″ further includes a second charge blocking layer 402 formed on control dielectric layer 208. In FIG. 4, gate contact 118 is formed on second charge blocking layer 402. In an embodiment, second charge blocking layer 402 is formed of a high-k dielectric material, such as Al₂O₃, HfO₂, ZrO₂, HfAlO₃, etc., preferably HfO₂. In embodiments, second charge blocking layer 402 may be formed of any of the materials described above for first charge blocking layer 206, and may be configured similarly, such as in a single layer configuration (uniform or gradient of material) or multi-layer configuration.

Charge blocking layers 206 and 402, which sandwich control dielectric layer 208, efficiently block charge transport through control dielectric layer 208. For example, first charge blocking layer 206 (e.g., HfO₂) blocks electron current from charge storage layer 204 to gate contact 118 during a programming operation. Second charge blocking layer 402 (e.g., HfO₂) blocks electron current from gate contact 118 to charge storage layer 402 during an erase operation. In an embodiment, the thicknesses of first and second charge blocking layers 206 and 402 are thin, such as less than 5 nm.

Another advantage of the first and second charge blocking layer 206 and 402 is that, although high-k dielectric layers can themselves have traps, first and second charge blocking layers 206 and 402 can be made very thin, such as less than 2 nm, to reduce a total amount of charge traps while efficiently blocking current flow. Furthermore, second charge blocking layer 402 is positioned adjacent to gate contact 118. Thus, even if a relatively large amount of charge is trapped in second charge blocking layer 402, an effect on the flat-band voltage is proportional to a distance from second charge blocking layer 402 to gate contact 118, which is minimal (since they may be directly adjacent to each other).

Some further example advantages of the embodiment of FIG. 4, where first and second charge blocking layers 206 and 402 are HfO₂, and control dielectric layer 208 is Al₂O₃, include:

1) An enhancement in the memory program/erase window is achieved. As used herein, a program/erase (P/E) window is the voltage difference between threshold states of a program state and an erase state. With gate stack 120″, memory device 100 can be erased (e.g., up to −6V), with a P/E window of 12.8V or greater. In example embodiments, the P/E window can range from about 8 V to about 16 V (e.g., in example ranges of about 9 V to about 14V, about 10 V to about 13V, or have example values of about 9 V, about 10 V, about 11V, about 12V, or about 13V). With scaling of tunneling dielectric layer 202 to 6 nm in a +/−20V P/E limit, the P/E window can be as large as 14.2V, approaching multi-state memory voltage requirements, such as for 3-bit or even 4-bit memory cells;

(2) The P/E window does not show significant drift after 100,000 P/E cycles; and

(3) Charge is retained in charge storage layer 204 at a 12V P/E window, and more importantly 100,000 P/E cycles do not degrade the charge retention characteristics.

In some embodiments of memory device 100, charge storage layer 204 is a single continuous region. For example, FIG. 4 shows a plan view of charge storage layer 204 having a planar, continuous configuration. For example, charge storage layer 204 may be formed from a continuous film of silicon (or polysilicon), a metal, etc. In such a configuration, if a single point of the continuous region breaks down and begins to lose charge, the entire region can lose its charge, causing memory device 100 to lose its programmed state. However, some embodiments of the present invention offer some protection from this problem. For example, FIG. 6 shows a plan view of charge storage layer 204 having a non-continuous configuration, according to an embodiment of the present invention. In the example of FIG. 6, charge storage layer 204 comprises a plurality of nanoparticles 602. Because nanoparticles 602 of charge storage layer 204 each separately store charge, and are insulated from one another, even if a single nanoparticle loses charge, this will not likely affect the remaining nanoparticles of charge storage layer 204. Thus, a memory device incorporating a charge storage layer 204, according to the present invention, is more likely to maintain a constant programmed state, over a much longer time than conventional memory devices.

In an embodiment, nanoparticles 602 are electrically isolated nanocrystals. Nanocrystals are small clusters or crystals of a conductive material that are electrically isolated from one another. One advantage in using nanocrystals for charge storage layer 204 is that they do not form a continuous film, and thus charge storages formed of nanocrystals are self-isolating. Because nanocrystals form a non-continuous film, charge storage layers can be formed without worrying about shorting of the charge storage medium of one cell level to the charge storage medium of adjacent cells lying directly above or below (i.e., vertically adjacent). Yet another advantage of the use of nanocrystals for charge storage layers is that they experience less charge leakage than do continuous film charge storage layers.

Nanocrystals can be formed from conductive material such as palladium (Pd), iridium (Ir), nickel (Ni), platinum (Pt), gold (Au), ruthenium (Ru), cobalt (Co), tungsten (W), tellurium (Te), rhenium (Re), molybdenum (Mo), iron platinum alloy (FePt), tantalum nitride (TaN), etc. Such materials generally have a higher work function (e.g., about 4.5 eV or higher) than many semiconductors such as silicon, which is desirable for multiple electron storage, have a higher melting point (which allows a higher thermal budget), have longer retention times, and have high density of states for both positive and negative charge storage.

Methods for forming nanocrystals are well known in the art, for example, as disclosed in U.S. application Ser. No. 11/506,769, filed Aug. 18, 2006, the disclosure of which is incorporated herein by reference in its entirety. A metal nanocrystal charge storage layer can be formed by physical vapor deposition (PVD) or (atomic layer deposition) in which a thin film is first deposited on a surface of a substrate (e.g., by sputtering using PVD) and then annealed at high temperature (e.g., about 900 degrees C. or higher) for a short time (e.g., about 10 seconds) to coalesce metal particles of nanoscale dimensions. The uniformity and size of the metal particles can be controlled by varying the thickness of the sputtered metal layer, the annealing temperature and annealing time, pressure, and ambient gas species, etc. When silicon nanocrystals are used in charge storage layer 204, the silicon nanocrystals may be formed by a process such as CVD as described, for example, in U.S. Pat. No. 6,297,095, which is incorporated by reference herein in its entirety. Charge storage layer 204 may include preformed colloidal metal or semiconductor quantum dots deposited on the tunneling dielectric layer 202 by methods such as spin coating, spray coating, printing, chemical self-assembly and the like. For example, such processes are described in U.S. Pat. No. 6,586,785, U.S. application Ser. No. 11/147,670, and U.S. application Ser. No. 11/495,188, which is each incorporated by reference herein in its entirety.

Additionally, instead of including a dielectric isolated charge storage layer for charge storage in memory device 100, a nonconductive trapping layer formed in a dielectric stack of the gate stack may be used. For example, the charge storage medium can be a dielectric stack comprising a first oxide layer (e.g., tunneling dielectric layer 202) adjacent to channel region 114, a nonconductive nitride layer adjacent to the first oxide layer, and a second oxide layer adjacent to the nitride layer and adjacent to gate contact 118. Such a dielectric stack is sometimes referred to as an ONO stack (i.e., oxide-nitride-oxide) stack. The second oxide layer can be replaced with one of gate stacks 120, 120′, or 120″ to improve the performance of the traditional ONO stack. Other suitable charge trapping dielectric films such as an H+ containing oxide film can be used if desired.

### Example Embodiments

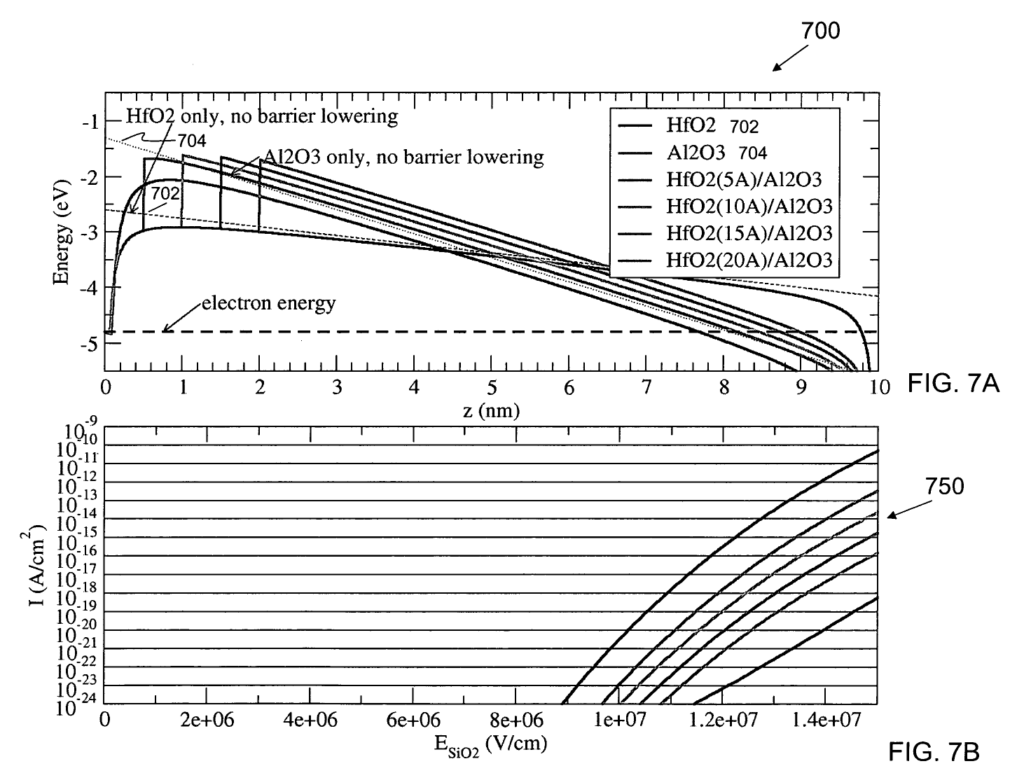

In an example embodiment, charge storage layer 204 includes metal dots, charge blocking layer 206 is HfO₂, and control dielectric layer 208 is Al₂O₃. FIG. 7A shows a simulation plot 700 of energy (eV) versus a thickness (nm) of a combination control dielectric of charge blocking layer 206 (HfO₂) and control dielectric layer 208 (Al₂O₃). FIG. 7B shows a simulation plot 750 of current (A/cm²) versus electric field (V/cm). Plot 700 shows a plot line 702 for the combination control dielectric only including HfO₂, and a plot line 704 for the combination control dielectric only including Al₂O₃. For both of plot lines 702 and 704, no barrier lowering is indicated. Plots 700 and 750 show that including a thin layer of HfO₂ at the interface of metal and Al₂O₃ can reduce the electron tunneling current by many orders of magnitude. This is true even if the HfO₂ layer is less than 1 nm thick.

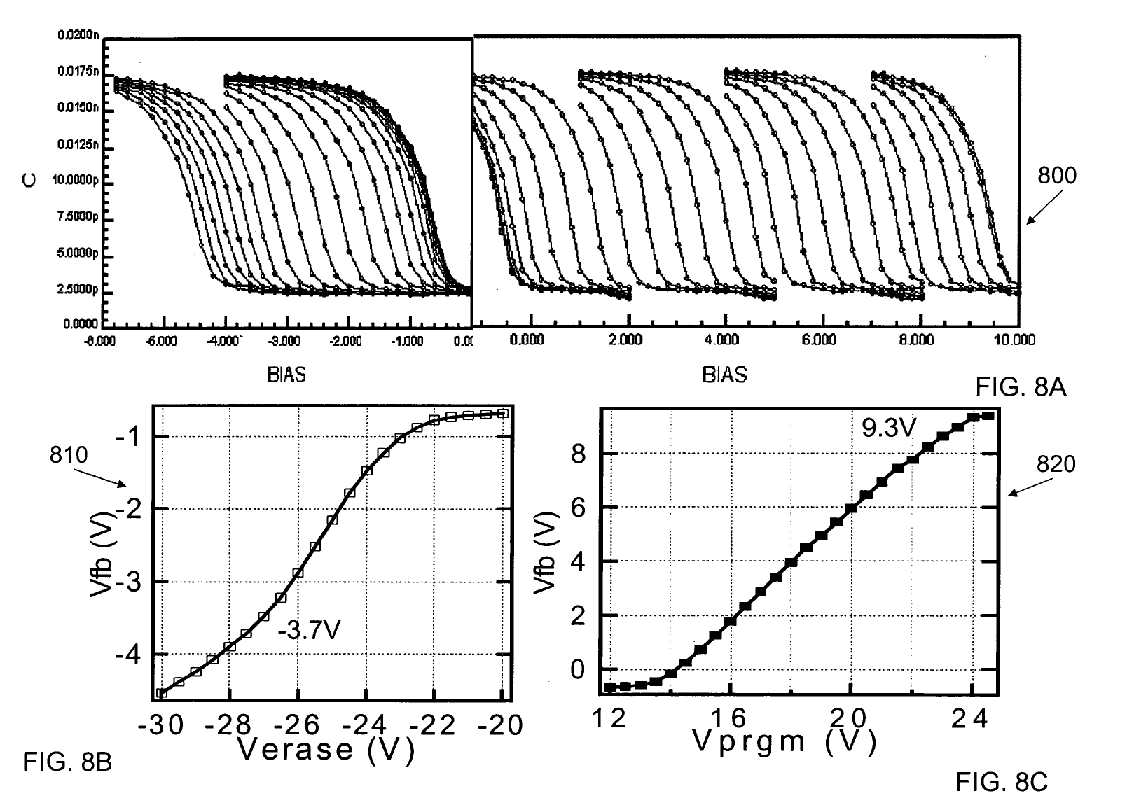

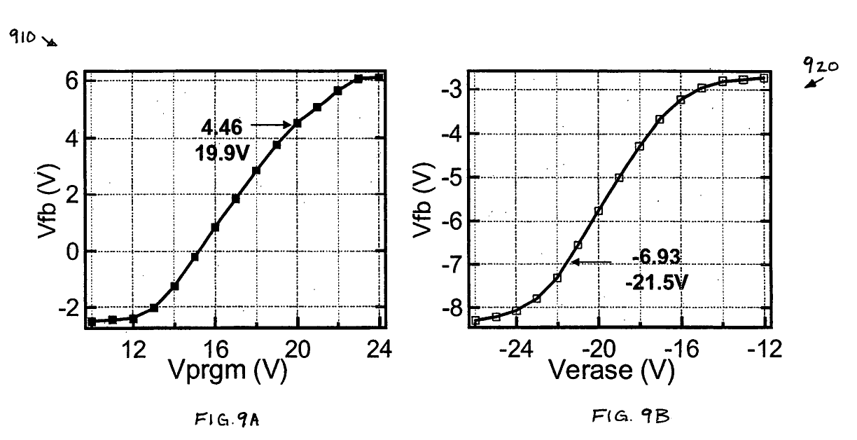

FIGS. 8A-8C respectively show plots 800, 810, and 820 related to an example gate stack similar to gate stack 120 shown in FIG. 2. A shown in FIG. 8B, an erase voltage is approximately 3.7V and a program voltage is approximately 9.3V, for a total P/E window of 13 V.

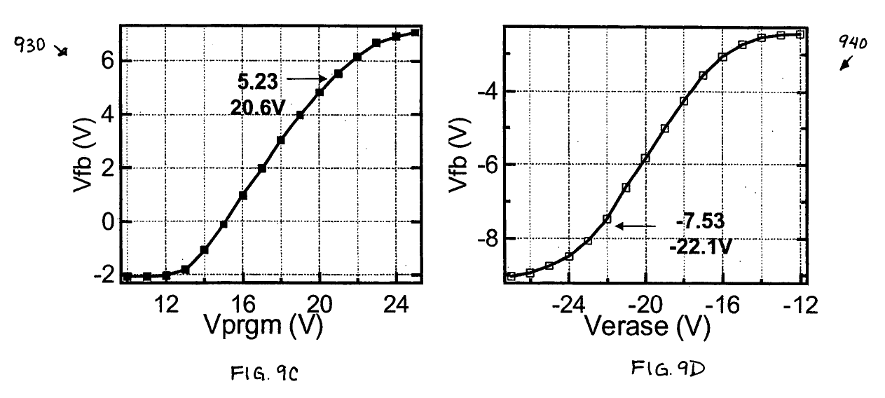

FIGS. 9A and 9B respectively show plots 910 and 920 related to an example gate stack similar to gate stack 120″ shown in FIG. 4. In this example, charge storage layer 204 is formed of quantum dots, first charge blocking layer 206 is formed of HfO₂ having a thickness of 4 nm, control dielectric layer 208 is formed of Al₂O₃ at a thickness of 12 nm, and second charge blocking layer 402 is formed of HfO₂ at a thickness of 4 nm. As indicated by plots 910 and 920, a P/E linear window is approximately 11.39V.

FIGS. 9C and 9D respectively show plots 930 and 940 related to an example gate stack similar to gate stack 120″ shown in FIG. 4. In this example, charge storage layer 204 is formed of quantum dots, first charge blocking layer 206 is formed of HfO₂ having a thickness of 4 nm, control dielectric layer 208 is formed of Al₂O₃ at a thickness of 12 nm, and second charge blocking layer 402 is formed of HfO₂ at a thickness of 8 nm. As indicated by plots 930 and 940, a P/E linear window is approximately 12.76V.

### Multistate Memory Embodiments

A memory device may have any number of memory cells. In a conventional single-bit memory cell, a memory cell assumes one of two information storage states, either an “on” state or an “off” state. The binary condition of “on” or “off” defines one bit of information. As a result, a conventional memory device capable of storing n-bits of data requires (n) separate memory cells.

The number of bits that can be stored using single-bit per cell memory devices depends upon the number of memory cells. Thus, increasing memory capacity requires larger die sizes containing more memory cells, or using improved photolithography techniques to create smaller memory cells. Smaller memory cells allow more memory cells to be placed within a given area of a single die.

An alternative to a single-bit memory cell is a multi-bit or multistate memory cell, which can store more than one bit of data. A multi-bit or multistate flash memory cell may be produced by creating a memory cell with multiple, distinct threshold voltage levels, Vₜ₁₋ₙ, as described, for example, in U.S. Pat. No. 5,583,812, which is incorporated by reference herein in its entirety. Each distinct threshold voltage level, Vₜ₁₋ₙ, corresponds to a value of a set of data bits, with the number of bits representing the amount of data that can be stored in the multistate memory cell. Thus, multiple bits of binary data can be stored within the same memory cell.

Each binary data value that can be stored in a multistate memory cell corresponds to a threshold voltage value or range of values over which the multistate memory cell conducts current. The multiple threshold voltage levels of a multistate memory cell are separated from each other by a sufficient amount so that a level of a multistate memory cell can be programmed or erased in an unambiguous manner. The specific relationship between the data programmed into the memory cell and the threshold voltage levels of the cell depends upon the data encoding scheme adopted for the multistate memory cell.

In programming a multistate memory cell, a programming voltage is applied over a sufficient time period to store enough charge in the charge storage layer to move the multistate memory cell's threshold voltage to a desired level. This level represents a state of the multistate memory cell, corresponding to an encoding of the data programmed into the multistate memory cell.

According to embodiments of the present invention, multiple threshold voltage levels for a multistate memory cell/device are provided in charge storage layer 204 by electrically isolated nanoparticles (such as shown in FIG. 6) or a contiguous or non-contiguous metal (or silicon) layer such as shown in FIG. 5.

In another embodiment of multi-bit memory cells as described for example in U.S. Pat. No. 5,768,192, which is incorporated by reference herein in its entirety, charge is stored in a non-conductive charge trapping layer (e.g., a nitride layer) in two physically distinct regions on opposite sides of the memory cell near the source and drain regions of the device. By developing symmetric and interchangeable source and drain regions in the cell, two non-interactive physically distinct charge storage regions are created, with each region physically representing one bit of information mapped directly to the memory array and each cell thereby containing two bits of information. Programming of the cell is performed in a forward direction which includes injecting electrical charge into the charge trapping material within the gate utilizing hot electron injection for a sufficient time duration such that electrical charge becomes trapped asymmetrically in the charge trapping material, the electrical charge being injected until the threshold voltage of the gate reaches a predetermined level. The cell is then read in the reverse direction from which it was programmed. This type of multi-bit memory cell can also be extended to charge storage layer memory devices using discrete metal nanocrystals as the charge storage medium, as described, for example, in U.S. Appl. Pub. No. 2004/0130941, which is incorporated by reference herein in its entirety.

The present inventors have also discovered that multi-bit storage using asymmetrical charge storage as described above can be accomplished using colloidal metal nanocrystals (e.g., as described in U.S. Pat. No. 6,586,785 and in U.S. application Ser. Nos. 11/147,670 and 11/495,188). The tighter control of the size and uniformity of such colloidal metal dots (e.g., over other deposited nanocrystals using PVD or CVD) has the advantage of relaxing the requirement on threshold spread by minimizing lateral charge conduction between adjacent dots when selectively charging a small portion of the nanocrystals near the source and/or drain of the device to produce the charging asymmetry.

A significant feature of the use of the devices and methods of the present invention is that it enables the reliable storage of multiple bits in a single device using, e.g., any of the conventional techniques for generating multi-state memory as described herein. Conventional flash memories using multi-bit storage achieved through the above-described methods such as the multi-level approach suffer from the stringent requirements on the control of the threshold spread. The present invention, however, overcomes many of the limitations of conventional flash memory devices by providing a large programming/erase window (e.g., on the order of 12 volts or greater), increased programming/erasing speed and good charge retention as shown in Appendix A. This allows for a greater separation between the various threshold voltage states from each other so that a level of a multistate memory cell can be programmed or erased in an unambiguous manner.

The present invention can also further enable the storage of multiple bits, such as three or more (e.g., four) bits per cell by, e.g., storing charge in each of two different storage locations in the charge storage layer (e.g., which can be a nanocrystal layer or a non-conductive nitride layer as described above), and further adding the ability to store different quantities or charge states in each of the two locations using e.g., multiple voltage threshold levels as described above. By storing four different quantities of charge at each location the memory device can thereby store 4×4=16 different combinations of charge providing the equivalent of four bits per cell. The enhancement in program/erase window provided by the teachings described herein without compromising charge retention further enables such multi-bit storage capability by providing greater flexibility in the injection and detection of charge in the storage medium and a relaxed requirement on threshold spread.

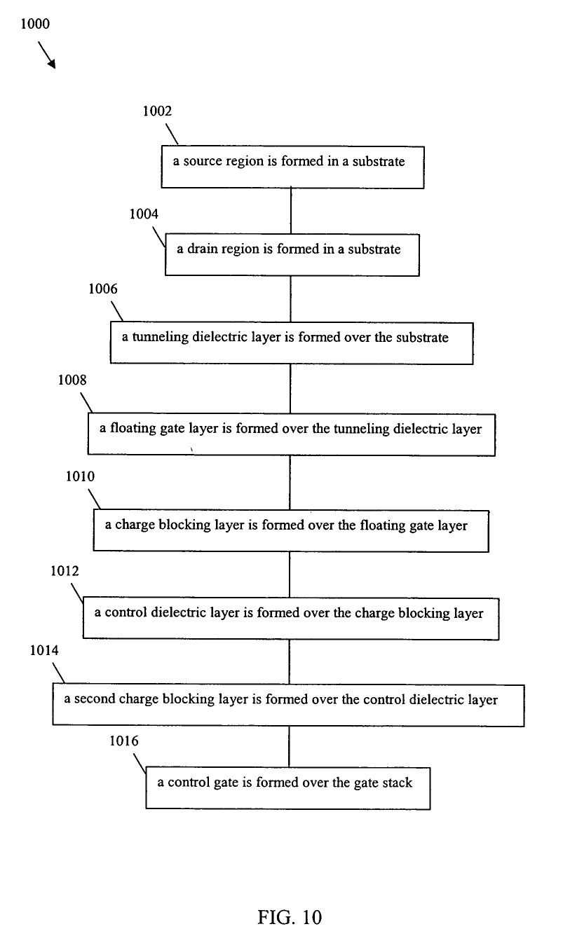

Embodiments of the present invention may be assembled according to well known semiconductor manufacturing techniques. FIG. 10 shows a flowchart 1000 providing example steps for forming an electronic device, such as a memory device, according to example embodiments of the present invention. Flowchart 1000 is provided for illustrative purposes, but is not intended to be limiting. Further structural and operational embodiments will be apparent to persons skilled in the relevant art(s) based on the following discussion. The steps of flowchart 1000 do not necessarily have to occur in the order shown.

Flowchart 1000 begins with step 1002. In step 1002, a source region is formed in a substrate. For example, as shown in FIGS. 2 and 4, source region 112 may be formed in substrate 102. Source region 112 may be formed according to conventional doping or other techniques. Furthermore, in an embodiment, source contact 104 may be formed on source region 112 according to conventional deposition or other techniques.

In step 1004, a drain region is formed in a substrate. For example, as shown in FIGS. 2 and 4, drain region 116 may be formed in substrate 102. Drain region 116 may be formed according to conventional doping or other techniques. Furthermore, in an embodiment, drain contact 106 may be formed on drain region 116 according to conventional deposition or other techniques.

In step 1006, a tunneling dielectric layer is formed over the substrate. For example, as shown in FIGS. 2 and 4, tunneling dielectric layer 202 may be formed over channel region 114 of substrate 102. Tunneling dielectric layer 202 may be formed according to conventional oxide growth or other techniques.

In step 1008, a charge storage layer is formed over the tunneling dielectric layer. For example, as shown in FIGS. 2 and 4, charge storage layer 204 may be formed over tunneling dielectric layer 202. In an embodiment, charge storage layer 204 is formed directly on tunneling dielectric layer 202. In another embodiment, charge storage layer 204 is formed on an intermediate layer formed on tunneling dielectric layer 202, such as barrier layer 302 shown in FIG. 3.

Charge storage layer 204 may be a metal or semiconductor material layer (continuous or non-continuous) or a layer of particles, such as further described above. Charge storage layer 204 may be formed according to deposition techniques such as physical vapor deposition (PVD), chemical vapor deposition (CVD), electrochemical deposition (ECD), molecular beam epitaxy (MBE), atomic layer deposition (ALD), or other techniques described elsewhere herein or otherwise known.

In step 1010, a charge blocking layer is formed over the charge storage layer. For example, as shown in FIGS. 2 and 4, charge blocking layer 206 is formed over charge storage layer 204. Charge blocking layer 206 may be formed according to any deposition technique described elsewhere herein or otherwise known. In an embodiment, as described above, charge blocking layer 206 may be doped. Furthermore, in an embodiment, as described above, charge blocking layer 206 may be formed as a gradient or as having multiple layers.

In step 1012, a control dielectric layer is formed over the charge blocking layer. For example, as shown in FIGS. 2 and 4, control dielectric layer 208 is formed over charge blocking layer 206. Control dielectric layer 208 may be formed according to any deposition technique described elsewhere herein or otherwise known.

In step 1014, a second charge blocking layer is formed over the control dielectric layer. Step 1014 is not necessarily performed in all embodiments. For example, FIG. 2 shows gate stack 120 that does not include a second charge blocking layer. Alternatively, as shown in FIG. 4, second charge blocking layer 402 is formed over control dielectric layer 208. Second charge blocking layer 402 may be formed according to any deposition technique described elsewhere herein or otherwise known. In an embodiment, in a similar fashion to first charge blocking layer 206, second charge blocking layer 402 may be doped. Furthermore, in an embodiment, in a similar fashion to first charge blocking layer 206, second charge blocking layer 402 may be formed as a gradient or as having multiple layers.

In step 1016, a control gate is formed over the gate stack. For example, as shown in FIG. 2, gate contact 118 is formed over control dielectric layer 208 of gate stack 120. As shown in FIG. 4, gate contact 118 is formed over second charge blocking layer 402 of gate stack 120″. Gate contact 118 may be formed on gate stacks 120 and 120″ according to conventional deposition or other techniques.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A memory device, comprising:
a substrate;
a source region of the substrate;
a drain region of the substrate;
a channel region between the source region and drain region;
a tunneling dielectric layer over the substrate adjacent to the channel region;
a charge storage layer over the tunneling dielectric layer;
a charge blocking layer over the charge storage layer;
a control dielectric layer over the charge blocking layer; and
a control gate over the control dielectric layer.

2. The memory device of claim 1, wherein the charge storage layer comprises at least one of physical vapor deposition (PVD) dots, chemical vapor deposition (CVD) dots, or colloidal dots.

3. The memory device of claim 1, wherein the charge storage layer is a continuous metal or semiconducting layer.

4. The memory device of claim 1, wherein the charge storage layer is a non-contiguous metal or semiconducting layer.

5. The memory device of claim 1, wherein the charge storage layer comprises a plurality of nanoparticles.

6. The memory device of claim 1, wherein the charge storage layer comprises a nitride layer.

7. The memory device of claim 5, wherein the nanoparticles are nanocrystals.

8. The memory device of claim 1, wherein said tunneling dielectric layer comprises an oxide.

9. The memory device of claim 1, wherein the control dielectric layer is Al₂O₃.

10. The memory device of claim 1, further comprising:
a barrier layer between the tunneling dielectric layer and the charge storage layer.

11. The memory device of claim 10, wherein the barrier layer comprises nitrogen.

12. The memory device of claim 1, wherein the charge blocking layer comprises HfO₂.

13. The memory device of claim 1, wherein the charge blocking layer comprises at least one of Al₂O₃, SiO₂, or HfAlO₃.

14. The memory device of claim 1, wherein the charge blocking layer is a high-k dielectric material.

15. The memory device of claim 1, wherein the charge blocking layer includes at least one of Gd₂O₃, Yb₂O₃, Dy₂O₃, Nb₂O₅, Y₂O₃, La₂O₃, ZrO₂, TiO₂, Ta₂O₅, SrTiO₃, BaxSr1-xTiO₃, ZrxSi1-xOy, HfxSi1-xOy, AlxZr1-xO₂, or Pr₂O.

16. The memory device of claim 1, wherein the charge blocking layer is formed as a gradient of material

17. The memory device of claim 1, wherein the charge blocking layer comprises a plurality of layers.

18. The memory device of claim 17, wherein the plurality of layers includes a first layer that is directly adjacent to the charge storage layer, wherein the first layer comprises a material having a higher band gap than a band gap of a material of a second layer of the plurality of layers.

19. The memory device of claim 1, wherein the charge blocking layer is doped with a dopant material.

20. The memory device of claim 19, wherein the dopant material is a rare earth metal or silicate.

21. The memory device of claim 1, wherein the charge blocking layer has a thickness less than about 4 nm.

22. The memory device of claim 1, wherein the charge blocking layer has a thickness less than about 2 nm.

23. The memory device of claim 1, wherein the charge blocking layer has a higher dielectric constant than the control dielectric layer.

24. The memory device of claim 1, further comprising:
a second charge blocking layer between the control dielectric layer and the control gate.

25. The memory device of claim 24, wherein the second charge blocking layer comprises HfO₂.

26. The memory device of claim 24, wherein the second charge blocking layer comprises at least one of Al₂O₃, SiO₂, or HfAlO₃.

27. The memory device of claim 24, wherein the second charge blocking layer is a high-k dielectric material.

28. The memory device of claim 24, wherein the second charge blocking layer includes at least one of Gd₂O₃, Yb₂O₃, Dy₂O₃, Nb₂O₅, Y₂O₃, La₂O₃, ZrO₂, TiO₂, Ta₂O₅, SrTiO₃, BaxSr1-xTiO₃, ZrxSi1-xOy, HfxSi1-xOy, AlxZr1-xO₂, or Pr₂O.

29. The memory device of claim 24, wherein the second charge blocking layer is formed as a gradient of material

30. The memory device of claim 24, wherein the second charge blocking layer comprises a plurality of layers.

31. The memory device of claim 30, wherein the plurality of layers includes a first layer that is directly adjacent to the control dielectric layer, wherein the first layer comprises a material having a higher band gap than a band gap of a material of a second layer of the plurality of layers.

32. The memory device of claim 24, wherein the second charge blocking layer is doped with a dopant material.

33. The memory device of claim 32, wherein the dopant material is a rare earth metal or silicate.

34. The memory device of claim 24, wherein the second charge blocking layer has a thickness less than about 4 nm.

35. The memory device of claim 24, wherein the second charge blocking layer has a thickness less than about 2 nm.

36. The memory device of claim 24, wherein the second charge blocking layer has a higher dielectric constant than the control dielectric layer.

37. The memory device of claim 24, wherein the memory device has a program/erase window of greater than about 9 volts.

38. The memory device of claim 37, wherein the program/erase window is greater than about 10 volts.

39. The memory device of claim 38, wherein the program/erase window is greater than about 11 volts.

40. The memory device of claim 39, wherein the program/erase window is greater than about 12 volts.

41. The memory device of claim 1, wherein the memory device is a non-volatile memory device.

42. The memory device of claim 1, wherein the memory device is a flash memory device.

43. A gate stack of a memory device, comprising:
a tunneling dielectric layer over a substrate of the memory device;
a charge storage layer over the tunneling dielectric layer;
a charge blocking layer over the charge storage layer; and
a control dielectric layer over the first charge blocking layer;
wherein a control gate is over the control dielectric layer.

44. The gate stack of claim 43, wherein the charge storage layer comprises at least one of physical vapor deposition (PVD) dots, chemical vapor deposition (CVD) dots, or colloidal dots.

45. The gate stack of claim 43, wherein the charge storage layer is a continuous metal or semiconducting layer.

46. The gate stack of claim 43, wherein the charge storage layer is a non-contiguous metal or semiconducting layer.

47. The gate stack of claim 43, wherein the charge storage layer comprises a plurality of nanoparticles.

48. The gate stack of claim 47, wherein the nanoparticles are nanocrystals.

49. The gate stack of claim 43, wherein the charge storage layer comprises a nitride layer.

50. The gate stack of claim 43, wherein said tunneling dielectric layer comprises an oxide.

51. The gate stack of claim 43, wherein the control dielectric layer is Al₂O₃.

52. The gate stack of claim 43, further comprising:
a barrier layer between the tunneling dielectric layer and the charge storage layer.

53. The gate stack of claim 52, wherein the barrier layer comprises nitrogen.

54. The gate stack of claim 43, wherein the charge blocking layer comprises HfO₂.

55. The gate stack of claim 43, wherein the charge blocking layer comprises at least one of Al₂O₃, SiO₂, or HfAlO₃.

56. The gate stack of claim 43, wherein the charge blocking layer is a high-k dielectric material.

57. The gate stack of claim 43, wherein the charge blocking layer includes at least one of HfAlO₃, Gd₂O₃, Yb₂O₃, Dy₂O₃, Nb₂O₅, Y₂O₃, La₂O₃, ZrO₂, TiO₂, Ta₂O₅, SrTiO₃, BaxSr1-xTiO₃, ZrxSi1-xOy, HfxSi1-xOy, AlxZr1-xO₂, or Pr₂O.

58. The gate stack of claim 43, wherein the charge blocking layer is formed as a gradient of material

59. The gate stack of claim 43, wherein the charge blocking layer comprises a plurality of layers.

60. The gate stack of claim 59, wherein the plurality of layers includes a first layer that is directly adjacent to the charge storage layer, wherein the first layer comprises a material having a higher band gap than a band gap of a material of a second layer of the plurality of layers.

61. The gate stack of claim 43, wherein the charge blocking layer is doped with a dopant material.

62. The gate stack of claim 61, wherein the dopant material is a rare earth metal or silicate.

63. The gate stack of claim 43, wherein the charge blocking layer has a thickness less than about 4 nm.

64. The gate stack of claim 43, wherein the charge blocking layer has a thickness less than about 2 nm.

65. The gate stack of claim 43, wherein the charge blocking layer has a higher dielectric constant than the control dielectric layer.

66. The gate stack of claim 43, further comprising:
a second charge blocking layer between the control dielectric layer and the control gate.

67. The gate stack of claim 66, wherein the second charge blocking layer comprises HfO₂.

68. The gate stack of claim 66, wherein the second charge blocking layer comprises at least one of Al₂O₃, SiO₂, or HfAlO₃.

69. The gate stack of claim 66, wherein the second charge blocking layer is a high-k dielectric material.

70. The gate stack of claim 66, wherein the second charge blocking layer includes at least one of HfAlO₃, Gd₂O₃, Yb₂O₃, Dy₂O₃, Nb₂O₅, Y₂O₃, La₂O₃, ZrO₂, TiO₂, Ta₂O₅, SrTiO₃, BaxSr1-xTiO₃, ZrxSi1-xOy, HfxSi1-xOy, AlxZr1-xO₂, or Pr₂O.

71. The gate stack of claim 66, wherein the second charge blocking layer is formed as a gradient of material

72. The gate stack of claim 66, wherein the second charge blocking layer comprises a plurality of layers.

73. The gate stack of claim 72, wherein the plurality of layers includes a first layer that is directly adjacent to the control dielectric layer, wherein the first layer comprises a material having a higher band gap than a band gap of a material of a second layer of the plurality of layers.

74. The gate stack of claim 66, wherein the second charge blocking layer is doped with a dopant material.

75. The gate stack of claim 74, wherein the dopant material is a rare earth metal or silicate.

76. The gate stack of claim 66, wherein the second charge blocking layer has a thickness less than about 4 nm.

77. The gate stack of claim 66, wherein the second charge blocking layer has a thickness less than about 2 nm.

78. The gate stack of claim 66, wherein the second charge blocking layer has a higher dielectric constant than the control dielectric layer.

79. The gate stack of claim 66, wherein the memory device has a program/erase window of greater than about 9 volts.

80. The gate stack of claim 79, wherein the program/erase window is greater than about 10 volts.

81. The gate stack of claim 80, wherein the program/erase window is greater than about 11 volts.

82. The gate stack of claim 81, wherein the program/erase window is greater than about 12 volts.

83. The gate stack of claim 43, wherein the memory device is a non-volatile memory device.

84. The gate stack of claim 43, wherein the memory device is a flash memory device.

85. A method for forming a memory device, comprising:
forming a tunneling dielectric layer over a substrate;
forming a charge storage layer over the tunneling dielectric layer;
forming a charge blocking layer over the charge storage layer;
forming a control dielectric layer over the charge blocking layer; and
forming a control gate over the control dielectric layer.

86. The method of claim 85, further comprising:
forming a source region of the substrate; and
forming a drain region of the substrate.

87. The method of claim 85, wherein the charge storage layer comprises quantum dots, further comprising:
forming the dots according to a physical vapor deposition (PVD) process, a chemical vapor deposition (CVD) process, or a colloidal dot process.

88. The method of claim 85, wherein said step of forming the charge storage layer comprises:
forming the charge storage layer as a continuous metal or semiconducting layer.

89. The method of claim 85, wherein said step of forming the charge storage layer comprises:
forming the charge storage layer as a non-contiguous metal or semiconducting layer.

90. The method of claim 85, wherein said step of forming the charge storage layer comprises:
forming a plurality of nanoparticles over the tunneling dielectric layer.

91. The method of claim 90, wherein the nanoparticles are nanocrystals.

92. The method of claim 85, wherein said step of forming the charge storage layer comprises:
forming the charge storage layer as a nitride layer.

93. The method of claim 85, wherein said step of forming the tunneling dielectric layer comprises:
oxidizing a surface of the substrate.

94. The method of claim 85, wherein said step of forming the control dielectric layer comprises:
forming a layer of Al₂O₃ over the charge blocking layer.

95. The method of claim 85, further comprising:
forming a barrier layer between the tunneling dielectric layer and the charge storage layer.

96. The method of claim 95, wherein said step of forming the barrier layer comprises:
depositing nitrogen or a nitrogen-containing compound to the tunneling dielectric layer using a chemical vapor deposition (CVD) process.

97. The method of claim 85, wherein said step of forming the charge blocking layer comprises:
forming a layer of HfO₂ over the charge storage layer.

98. The method of claim 85, wherein said step of forming the charge blocking layer comprises:
forming a layer of at least one of Al₂O₃, SiO₂, or HfAlO₃ over the charge storage layer.

99. The method of claim 85, wherein said step of forming the charge blocking layer comprises:
forming a layer of a high-k dielectric material over the charge storage layer.

100. The method of claim 85, wherein said step of forming the charge blocking layer comprises:
forming a layer of at least one of HfAlO₃, Gd₂O₃, Yb₂O₃, Dy₂O₃, Nb₂O₅, Y₂O₃, La₂O₃, ZrO₂, TiO₂, Ta₂O₅, SrTiO₃, BaxSr1-xTiO₃, ZrxSi1-xOy, HfxSi1-xOy, AlxZr1-xO₂, or Pr₂O over the charge storage layer.

101. The method of claim 85, wherein said step of forming the charge blocking layer comprises:
forming a material over the charge storage layer as a gradient.

102. The method of claim 85, wherein said step of forming the charge blocking layer comprises:
forming a plurality of layers of dielectric material over the charge storage layer.

103. The method of claim 102, wherein said step of forming a plurality of layers comprises:
forming a first layer of the plurality of layers includes directly adjacent to the charge storage layer, the first layer comprising a material having a higher band gap than a band gap of a material of a second layer of the plurality of layers.

104. The method of claim 85, further comprising:
doping the charge blocking layer with a dopant material.

105. The method of claim 104, wherein said step of doping the charge blocking layer comprises:
doping the charge blocking layer with a rare earth metal or silicate.

106. The method of claim 85, wherein said step of forming the charge blocking layer comprises:
forming the charge blocking layer to have a thickness less than about 4 nm.

107. The method of claim 85, wherein said step of forming the charge blocking layer comprises:
forming the charge blocking layer to have a thickness less than about 2 nm.

108. The method of claim 85, wherein said step of forming the charge blocking layer comprises:
forming the charge blocking layer from a material that has a higher dielectric constant than a material of the control dielectric layer.

109. The method of claim 85, further comprising:
forming a second charge blocking layer over the control dielectric layer to be positioned between the control dielectric layer and the control gate.

110. The method of claim 109, wherein said step of forming the second charge blocking layer comprises:
forming a layer of HfO₂ over the control dielectric layer.

111. The method of claim 109, wherein said step of forming the second charge blocking layer comprises:
forming a layer of at least one of Al₂O₃, SiO₂, or HfAlO₃ over the control dielectric layer.

112. The method of claim 109, wherein said step of forming the second charge blocking layer comprises:
forming a layer of a high-k dielectric material over the control dielectric layer.

113. The method of claim 109, wherein said step of forming the second charge blocking layer comprises:
forming a layer of at least one of HfAlO₃, Gd₂O₃, Yb₂O₃, Dy₂O₃, Nb₂O₅, Y₂O₃, La₂O₃, ZrO₂, TiO₂, Ta₂O₅, SrTiO₃, BaxSr1-xTiO₃, ZrxSi1-xOy, HfxSi1-xOy, AlxZr1-xO₂, or Pr₂O over the control dielectric layer.

114. The method of claim 109, wherein said step of forming the second charge blocking layer comprises:
forming a material over the control dielectric layer as a gradient.

115. The method of claim 109, wherein said step of forming the second charge blocking layer comprises:
forming a plurality of layers of dielectric material over the control dielectric layer.

116. The method of claim 115, wherein said step of forming a plurality of layers comprises:
forming a first layer of the plurality of layers includes directly adjacent to the control dielectric layer, the first layer comprising a material having a higher band gap than a band gap of a material of a second layer of the plurality of layers.

117. The method of claim 109, further comprising:
doping the charge blocking layer with a dopant material.

118. The method of claim 117, wherein said step of doping the second charge blocking layer comprises:
doping the second charge blocking layer with a rare earth metal or silicate.

119. The method of claim 109, wherein said step of forming the second charge blocking layer comprises:
forming the second charge blocking layer to have a thickness less than about 4 nm.

120. The method of claim 109, wherein said step of forming the second charge blocking layer comprises:
forming the second charge blocking layer to have a thickness less than about 2 nm.

121. The method of claim 109, wherein said step of forming the second charge blocking layer comprises:
forming the second charge blocking layer from a material that has a higher dielectric constant than a material of the control dielectric layer.

122. The method of claim 109, wherein the memory device has a program/erase window of greater than about 9 volts.

123. The method of claim 122, wherein the program/erase window is greater than about 10 volts.

124. The method of claim 123, wherein the program/erase window is greater than about 11 volts.

125. The method of claim 124, wherein the program/erase window is greater than about 12 volts.

126. The method of claim 85, wherein the memory device is a non-volatile memory device.

127. The method of claim 85, wherein the memory device is a flash memory device.

128. The method of claim 85, further comprising:
configuring the memory device as a multi-state memory device.

129. A flash memory device, comprising:
a memory cell having a program/erase window of greater than about 9 volts.

130. The flash memory device of claim 129, wherein the program/erase window is greater than about 10 volts.

131. The flash memory device of claim 130, wherein the program/erase window is greater than about 11 volts.

132. The flash memory device of claim 131, wherein the program/erase window is greater than about 12 volts.

133. The flash memory device of claim 129, wherein the memory cell comprises a charge storage layer;
wherein the charge storage layer comprises quantum dots formed according to a physical vapor deposition (PVD) process, a chemical vapor deposition (CVD) process, or a colloidal dot process.
